(19) United States
(12) Patent Application Publication
(10) Pub. No.: US 2026/0304997 A1
(43) Pub. Date: Oct. 1, 2026

(54) Epitaxial Structure, Semiconductor Device and Manufacturing Method Thereof

(71) Applicant: Xiamen Changelight Co. Ltd., Xiamen (CN)

(72) Inventors: Zhiheng XING, Xiamen (CN); Zhao LIU, Xiamen (CN); Chengdan SHI, Xiamen (CN); Rongxin ZHU, Xiamen (CN); Xiangjing ZHUO, Xiamen (CN); Zhongbao LIN, Xiamen (CN); Wei CHENG, Xiamen (CN)

(73) Assignee: Xiamen Changelight Co. Ltd., Xiamen (CN)

(21) Appl. No.: 19/432,888

(22) Filed: Dec. 24, 2025

Related U.S. Application Data
(63) Continuation of application No. PCT/CN2025/103349, filed on Jun. 25, 2025.

(30) Foreign Application Priority Data
Apr. 1, 2025 (CN) 202510400383.X

(51) Int. Cl. H10F 55/255

(52) U.S. Cl. CPC H10F 55/255

(57) ABSTRACT

An epitaxial structure, a semiconductor device and a manufacturing method thereof are provided. The epitaxial structure includes a substrate and an epitaxial stack disposed on the substrate. The epitaxial stack includes: a first insulating isolation layer, a channel layer, a barrier layer, a second insulating isolation layer, an N-type semiconductor layer, an active region, and a P-type semiconductor layer, sequentially stacked from bottom to top on the substrate.

### CROSS-REFERENCE TO RELATED APPLICATIONS

This application is a continuation of PCT application No. PCT/CN2025/103349, filed on Jun. 25, 2025, which claims priority to Chinese Patent Application No. 202510400383.X, filed on Apr. 1, 2025, entitled “Epitaxial Structure, Semiconductor Device and Manufacturing Method Thereof”, the entire contents of which are incorporated herein by reference for all purposes.

### BACKGROUND

Solar-blind ultraviolet photodetector (UV-PDs) have advantages such as high signal-to-noise ratio and low false alarm rate, and are widely used in civilian and national defense fields requiring ultra-long distance and ultra-high precision, such as fire warning, ozone monitoring, high-voltage corona detection, missile identification and tracking, shipborne communication, and deep space exploration. Commercial UV-PDs are mainly silicon (Si)-based charge-coupled devices (CCDs), complementary metal-oxide-semiconductor (CMOS) devices, and photomultiplier tubes (PMTs). During operation, such devices require filters to exclude interference from visible light, and PMTs require the application of several thousand volts to achieve high gain, thereby increasing the volume and energy consumption of the detection system. Ultra-wide bandgap semiconductor gallium oxide (Ga₂O₃) material, with its bandgap as high as 4.9 eV and extremely high light absorption coefficient, is a highly potential candidate for preparing high-sensitivity, high-quantum-efficiency UV-PDs. Currently, Ga₂O₃ UV-PDs have demonstrated excellent imaging capabilities and will enable applications—such as medical—imaging, cosmic celestial observation, and daily ultraviolet protection.

However, the prior Ga₂O₃ solar-blind ultraviolet detectors consist of photodetectors (PDs) and an electrical signal processing system. The current generated by the PDs after detecting ultraviolet light needs to be processed by the electrical signal processing module to feedback detection information, which is not suitable for intuitive real-time monitoring scenarios and the miniaturization requirements of detectors.

### SUMMARY

The present disclosure is related to the technical field of semiconductor device manufacturing, and more specifically, relates to an epitaxial structure, a semiconductor device and a manufacturing method thereof.

According to a first aspect of the present disclosure, some embodiments provide an epitaxial structure. The epitaxial structure includes a substrate; and an epitaxial stack disposed on the substrate. The epitaxial stack includes: a first insulating isolation layer, a channel layer, a barrier layer, a second insulating isolation layer, an N-type semiconductor layer, an active region, and a P-type semiconductor layer, sequentially stacked from bottom to top on the substrate.

According to a second aspect of the present disclosure, some embodiments provide a semiconductor device. The semiconductor device includes an epitaxial structure including: a substrate and an epitaxial stack disposed on the substrate. The epitaxial stack includes: a first insulating isolation layer, a channel layer, a barrier layer, a second insulating isolation layer, an N-type semiconductor layer, an active region, and a P-type semiconductor layer sequentially stacked from bottom to top on the substrate.

According to a third aspect of the present disclosure, some embodiments provide a manufacturing method of a semiconductor device. The manufacturing method includes: forming an epitaxial stack on a substrate through a single epitaxial process. The epitaxial stack includes a first insulating isolation layer, a channel layer, a barrier layer, a second insulating isolation layer, an N-type semiconductor layer, an active region, and a P-type semiconductor layer sequentially stacked along a growth direction.

### BRIEF DESCRIPTION OF THE DRAWINGS

To describe the technical solutions in the embodiments of the present disclosure or the prior arts more clearly, the following briefly introduces the accompanying drawings required for describing the embodiments or the prior art. The accompanying drawings in the following description show merely some embodiments of the present application.

FIG. 1 is a schematic diagram of an epitaxial structure according to one or more embodiments of the present disclosure;

FIG. 2 is a schematic diagram of another epitaxial structure according to one or more embodiments of the present disclosure;

FIG. 3 is a schematic diagram of a semiconductor device according to one or more embodiments of the present disclosure;

FIG. 4 is a schematic diagram of another semiconductor device according to one or more embodiments of the present disclosure;

FIG. 5 is a schematic diagram of another semiconductor device according to one or more embodiments of the present disclosure;

FIG. 6 is a schematic diagram of another semiconductor device according to one or more embodiments of the present disclosure;

FIG. 7 is a top view of FIG. 6;

FIG. 8 is a schematic diagram of another semiconductor device according to one or more embodiments of the present disclosure;

FIG. 9 is a flowchart of a manufacturing method of a semiconductor device according to one or more embodiments of the present disclosure;

FIG. 10 is a cross-sectional view illustrating an epitaxial structure including the first mesa M1 according to one or more embodiments of the present disclosure;

FIG. 11 is a cross-sectional view illustrating an epitaxial structure including the first mesa M1 and the first electrode structure A according to one or more embodiments of the present disclosure;

FIG. 12 is a cross-sectional view illustrating an epitaxial structure including the first mesa M1, the second mesa M2, the third mesa M3, the fourth mesa M4, and the first electrode structure A according to one or more embodiments of the present disclosure;

FIG. 13 is a cross-sectional view illustrating an epitaxial structure including the first mesa M1, the second mesa M2, the third mesa M3, the fourth mesa M4, the first electrode structure A, and the third electrode structure C according to one or more embodiments of the present disclosure;

FIG. 14 is a cross-sectional view illustrating an epitaxial structure including the first mesa M1, the second mesa M2, the third mesa M3, and the fourth mesa M4 according to one or more embodiments of the present disclosure;

FIG. 15 is a cross-sectional view illustrating an epitaxial structure including through hole structures according to one or more embodiments of the present disclosure.

### DETAILED DESCRIPTION

To make the content of the present disclosure clearer, the technical solutions in the embodiments of the present application will be described clearly and completely below in conjunction with the accompanying drawings in the embodiments of the present application. The described embodiments are only a part of the embodiments of the present application, not all of them. Based on the embodiments in this application, all other embodiments obtained by a person of ordinary skill in the art shall fall within the scope of protection of this application.

Many specific details are set forth in the following description to facilitate a full understanding of this application. However, this application can also be implemented in other ways different from those described herein. Those skilled in the art can make similar modifications without departing from the concepts recited in this application. Therefore, this application is not limited by the specific embodiments disclosed below.

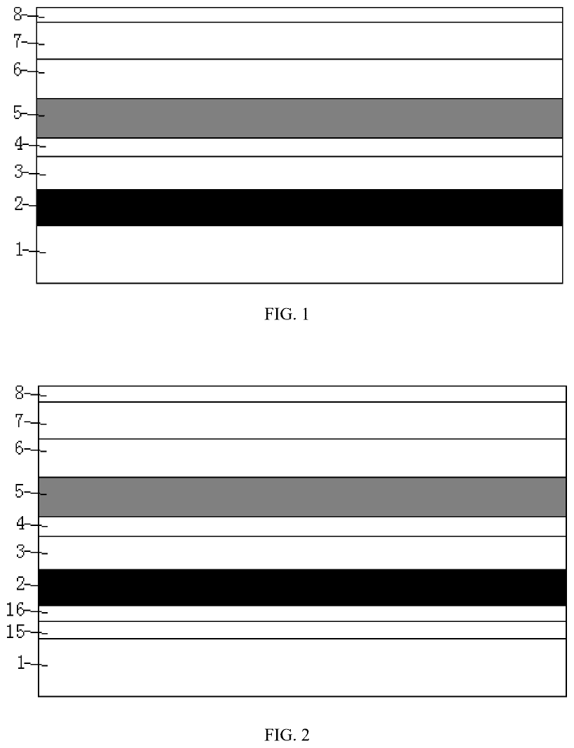

FIG. 1 is a schematic diagram of an epitaxial structure according to one or more embodiments of the present disclosure. As shown in FIG. 1, the epitaxial structure includes: substrate 1 and an epitaxial stack disposed on the substrate 1.

The epitaxial stack at least includes: a first insulating isolation layer 2, a channel layer 3, a barrier layer 4, a second insulating isolation layer 5, an N-type semiconductor layer 6, an active region 7, and a P-type semiconductor layer 8, sequentially stacked from bottom to top on the substrate 1.

In some embodiments of the present disclosure, the substrate 1 may be a Ga₂O₃ substrate (for example, a β—Ga₂O₃ substrate), or the channel layer 3 may be a GaN channel layer. The detailed materials of the substrate 1 and the channel layer 3 are not limited to the embodiments of the present disclosure.

In some embodiments of the present disclosure, the epitaxial stack may be obtained by a single epitaxial growth on the substrate 1, and the lattice constant of the first insulating isolation layer 2 may be between the lattice constant of the substrate 1 and the lattice constant of the channel layer 3.

In some embodiments of the present disclosure, the lattice constant of the second insulating isolation layer 5 may be between the lattice constant of the barrier layer 4 and the lattice constant of the N-type semiconductor layer 6.

In some embodiments of the present disclosure, the first insulating isolation layer 2 or the second insulating isolation layer 6 may include high-resistance nitride materials.

In some embodiments of the present disclosure, the first insulating isolation layer 2 or the second insulating isolation layer 5 may include, but are not limited to, a single nitride layer, or different combination structures of multiple nitride layers.

In some embodiments of the present disclosure, the first insulating isolation layer 2 or the second insulating isolation layer 5 may include, but are not limited to, a single AlN layer, a single C-doped GaN layer, a single Fe-doped GaN layer, an AlN/GaN superlattice structure, an AlN/AlGaN superlattice structure, or multiple AlGaN layers with different Al compositions.

In some embodiments of the present disclosure, the thickness range of the first insulating isolation layer 2 or the second insulating isolation layer 5 may be 0.02 μm to 3 μm, including endpoint values. For example, the thickness of the first insulating isolation layer 2 may be 0.02 μm, 1 μm, 2 μm, or 3 μm, and the thickness of the second insulating isolation layer 5 may be 0.02 μm, 1 μm, 2 μm, or 3 μm.

The specific materials and thicknesses of the first insulating isolation layer 2 and the second insulating isolation layer 5 are not limited to the embodiments of the present disclosure. The materials and thicknesses of the first insulating isolation layer 2 and the second insulating isolation layer 5 may be the same or different. In one or more embodiments of the present disclosure, the first insulating isolation layer 2 may be a C-doped GaN high-resistance layer with a thickness of 2 μm, and the second insulating isolation layer 5 may be a Fe-doped GaN high-resistance layer with a thickness of 1 μm.

In some embodiments of the present disclosure, the thickness range of the Channel layer 3 may be 10 nm to 1500 nm, including endpoint values. For example, the thickness of the Channel layer 3 may be 10 nm, or 100 nm, or 200 nm, or 300 nm, or 1500 nm.

In some embodiments of the present disclosure, the barrier layer 4 may include, but is not limited to, one or more of an AlN layer, an AlGaN layer, an InAlGaN layer, an InAlN layer, and an AlN/GaN superlattice structure.

In some embodiments of the present disclosure, the thickness range of the barrier layer 4 may be 2 nm to 40 nm, including endpoint values. For example, the thickness of the barrier layer 4 may be 2 nm, 20 nm, or 40 nm.

In some embodiments of the present disclosure, the thickness range of the N-type semiconductor layer 6 may be 0.5 μm to 4 μm, including endpoint values. For example, the thickness of the N-type semiconductor layer 6 may be 0.5 μm, 2 μm, or 4 μm.

In some embodiments of the present disclosure, the thickness range of the P-type semiconductor layer 8 may be 20 nm to 300 nm, including endpoint values. For example, the thickness of the P-type semiconductor layer 8 may be 20 nm, 50 nm, 100 nm, 200 nm, or 300 nm.

In some embodiments of the present disclosure, the active region 7 may be a periodic structure including well layers and barrier layers. The thickness range of the active region 7 may be 10 nm to 200 nm, including endpoint values. For example, the thickness of the active region 7 may be 10 nm, 50 nm, 100 nm, or 200 nm.

The specific materials of the N-type semiconductor layer 6 and the P-type semiconductor layer 8 are not limited to the embodiments of the present disclosure. In one or more embodiments of the present disclosure, the N-type semiconductor layer 6 may be an N-type GaN layer, the P-type semiconductor layer 8 may be a P-type GaN layer, and the active region 7 may be an InGaN/GaN multiple quantum well layer.

In some embodiments of the present disclosure, as shown in FIG. 2, the epitaxial stack may further include a nucleation layer 15 and a buffer layer 16 located between the substrate 1 and the first insulating isolation layer 2 and sequentially stacked in the direction toward the first insulating isolation layer 2, used for lattice transition and effectively reducing stress, which can further improve the crystal quality of the epitaxial stack.

In some embodiments of the present disclosure, the nucleation layer 15 may include, but is not limited to, one or more of an AlN layer, a GaN layer, and an AlGaN layer.

In some embodiments of the present disclosure, the thickness range of the nucleation layer 15 may be 5 nm to 500 nm, including endpoint values. For example, the thickness of the nucleation layer 15 may be 5 nm, or 200 nm, or 500 nm.

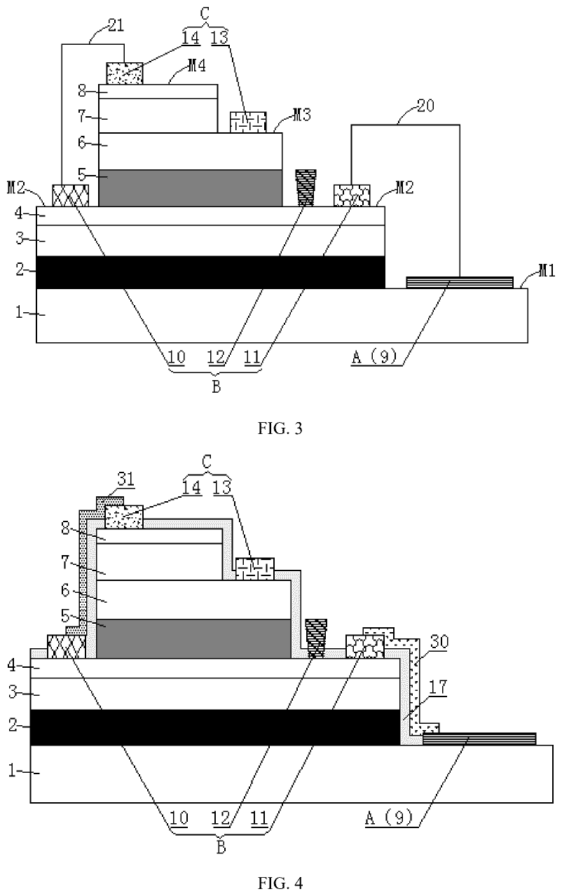

FIG. 3 is a schematic diagram of a semiconductor device according to one or more embodiments of the present disclosure. As shown in FIG. 3, the semiconductor device may include: The epitaxial structure described in any of the above embodiments, a first electrode structure A, a second electrode structure B, and a third electrode structure C. A side of the substrate 1 facing the epitaxial stack has a first mesa M1, a side of the barrier layer 4 away from the Channel layer 3 has a second mesa M2, a side of the N-type semiconductor layer 6 away from the second insulating isolation layer 5 has a third mesa M3, and a side of the P-type semiconductor layer 8 away from the active region 7 is a fourth mesa M4.

The first electrode structure A is located on the first mesa M1, and configured with the substrate 1 as a photodetector (PD). The second electrode structure B is located on the second mesa M2, and configured with the channel layer 3 and the barrier layer 4 as a transistor. The third electrode structure C is located on the third mesa M3 and the fourth mesa M4, and configured with the N-type semiconductor layer 6, the active region 7, and the P-type semiconductor layer 8 as a light-emitting diode (LED).

The PD, the transistor, and the LED are electrically connected in series sequentially, and the first electrode structure A, the second electrode structure B, and the third electrode structure C are all insulated from the sidewalls of the epitaxial stack.

In some embodiments of the present disclosure, the transistor may include a high electron mobility transistor (HEMT).

In some embodiments of the present disclosure, the first electrode structure A may be a PD electrode 9;

The second electrode structure B may include: a drain pad 10, a source pad 11, and a gate pad 12, wherein the drain pad 10 and the source pad 11 both form Ohmic contacts with the barrier layer 4, and the gate pad 12 forms a Schottky contact with the barrier layer 4;

The third electrode structure C may include: an N electrode 13 located on the third mesa M3 and a P electrode 14 located on the fourth mesa M4.

After the semiconductor device is connected to a working power supply, the photocurrent flows from the PD electrode 9 into the source pad 11 of the transistor, then flows out from the drain pad 10 of the transistor, then flows into the P electrode 14 of the LED, and then flows out from the N electrode 13 of the LED.

In some embodiments of the present disclosure, the drain pad 10, the source pad 11, and the gate pad 12 may be spaced apart from each other, and the N electrode 13 and the P electrode 14 may be arranged away from each other.

In some embodiments of the present disclosure, the PD electrode 9 may include, but is not limited to, an interdigitated electrode. The interdigitated electrode may include alternately arranged finger-shaped electrodes, forming dense electrode pairs, which can improve carrier collection efficiency. A parallel electric field may be formed between adjacent finger-shaped electrodes, making the electric field distribution more uniform, thereby improving the performance of the photodetector.

In some embodiments of the present disclosure, the drain pad 10 and the source pad 11 may be located on both sides of the gate pad 12, and the gate pad 12 may be used to control the current to achieve field-effect modulation.

In some embodiments of the present disclosure, the drain pad 10 may be disposed close to the P electrode side to facilitate subsequent connection between the drain pad 10 and the P electrode.

In some embodiments of the present disclosure, the second insulating isolation layer 5 and the LED may be located between the source pad 11 and the gate pad 12. The second insulating isolation layer 5 can improve the dielectric withstand capability between the source pad 11 and the gate pad 12, thereby enhancing the withstand voltage capability of the HEMT.

In some embodiments of the present disclosure, referring to FIG. 3, the second insulating isolation layer 5 and the LED may be located between the drain pad 10 and the gate pad 12. The second insulating isolation layer 5 can improve the dielectric withstand capability between the drain pad 10 and the gate pad 12, thereby enhancing the withstand voltage capability of the HEMT, and the gate pad 12 may be disposed close to the source pad 11 to reduce field-effect modulation delay.

In some embodiments of the present disclosure, the epitaxial structure used in the semiconductor device may include: an epitaxial stack obtained by a single epitaxial growth on the substrate 1. Using the epitaxial stack obtained by a single epitaxial growth, the photodetector, the transistor, and the LED may be integrated in the same module in a vertically stacked manner through epitaxy.

In some embodiments of the present disclosure, the PD electrode 9 may include, but is not limited to, one or more metal stacks of a Ti layer and an Au layer, wherein the thickness of the Ti layer may be 20 nm, and the thickness of the Au layer may be 120 nm.

In some embodiments of the present disclosure, the gate pad 12 may include, but is not limited to, one or more metal stacks of an Ni layer and an Au layer, wherein the thickness of the Ni layer may be 60 nm, and the thickness of the Au layer may be 100 nm.

In some embodiments of the present disclosure, the source pad 11 may include, but is not limited to, one or more metal stacks of a Ti layer, an Al layer, an Ni layer, and an Au layer, wherein the thickness of the Ti layer may be 20 nm, the thickness of the Al layer may be 120 nm, the thickness of the Ni layer may be 40 nm, and the thickness of the Au layer may be 50 nm.

In some embodiments of the present disclosure, the drain pad 10 may include, but is not limited to, one or more metal stacks of a Ti layer, an Al layer, an Ni layer, and an Au layer, wherein the thickness of the Ti layer may be 20 nm, the thickness of the Al layer may be 120 nm, the thickness of the Ni layer may be 40 nm, and the thickness of the Au layer may be 50 nm.

In some embodiments of the present disclosure, the connection between the photodetector and the transistor, and the connection between the transistor and the LED may be achieved by external wire bonding.

Specifically, referring to FIG. 3, the PD electrode 9 of the PD may be electrically connected to the source pad 11 of the transistor through a first external metal connection line 20, and the drain pad 10 of the transistor may be electrically connected to the P electrode 14 of the LED through a second external metal connection line 21.

In some embodiments of the present disclosure, as shown in FIG. 4, the semiconductor device further may include a passivation layer 17 covering the exposed surfaces of the epitaxial stack.

The first electrode structure A, the second electrode structure B, and the third electrode structure C are insulated from the sidewalls of the epitaxial stack through the passivation layer 17. The material of the passivation layer 17 may be silicon oxide, silicon nitride, or other materials with passivation effects, which is not limited to the embodiments of the present disclosure.

In some embodiments of the present disclosure, the connection between the photodetector and the transistor, and the connection between the transistor and the LED can also be achieved by directly setting metal connection lines on the passivation layer, without the need for additional external wire bonding.

Specifically, referring to FIG. 4, the PD electrode 9 of the photodetector may be electrically connected to the source pad 11 of the transistor through a first internal metal connection line 30, and the drain pad 10 of the transistor may be electrically connected to the P electrode 14 of the LED through a second internal metal connection line 31.

In some embodiments of the present disclosure, as shown in FIG. 5, the passivation layer 17 covers the exposed surfaces of the second electrode structure B and the third electrode structure C, and exposes the first electrode structure A. The passivation layer 17 may include through hole structures K1-K5 penetrating through the passivation layer 17. The first electrode structure A, the second electrode structure B, and the third electrode structure C are electrically connected to the epitaxial stack on the substrate 1 through these through hole structures K1-K5.

In one or more embodiments of the present disclosure, the through hole structures K1-K5 of the passivation layer 17 may include a first through hole K1, a second through hole K2, a third through hole K3, a fourth through hole K4, and a fifth through hole K5 penetrating through the passivation layer 17. The semiconductor device may further include: a first pad P1, a second pad P2, a third pad P3, a fourth pad P4, a fifth pad P5, and a sixth pad P6 located on a side of the passivation layer 17 away from the substrate 1. The first pad P1 may be connected to the drain pad 10 by embedding in the first through hole K1; the second pad P2 may be connected to the P electrode 14 by embedding in the second through hole K2; the third pad P3 may be connected to the N electrode 13 by embedding in the third through hole K3; the fourth pad P4 may be connected to the gate pad 12 by embedding in the fourth through hole K4; the fifth pad P5 may be connected to the source pad 11 by embedding in the fifth through hole K5; the sixth pad P6 may be connected to the PD electrode 9 by extending to the sidewall of the passivation layer 17.

The first electrode structure A may be exposed to avoid the passivation layer 17 affecting the photoelectric reception of the photodetector.

The materials of the first pad P1, the second pad P2, the third pad P3, the fourth pad P4, the fifth pad P5, or the sixth pad P6 may include, but are not limited to, one or more metal stacks of Al, Cu, Au, TiN, Ti, Pt, Cr, Ni, Pd. The detailed materials of the pads are not limited to the embodiments of the present application.

In one or more embodiments of the present disclosure, the material of the first pad P1, the second pad P2, the third pad P3, the fourth pad P4, the fifth pad P5, or the sixth pad P6 may be Al.

The specific thickness of the passivation layer 17 is not limited to the embodiments of the present disclosure. In one or more embodiments of the present disclosure, the thickness of the passivation layer 17 may be 2 μm.

In some embodiments of the present disclosure, the surfaces of the first pad P1, the second pad P2, the third pad P3, the fourth pad P4, the fifth pad P5, and the sixth pad P6 away from the passivation layer 17 may be at the same level height, which can reduce soldering defects and avoid device tilting or suspension, thereby improving device stability.

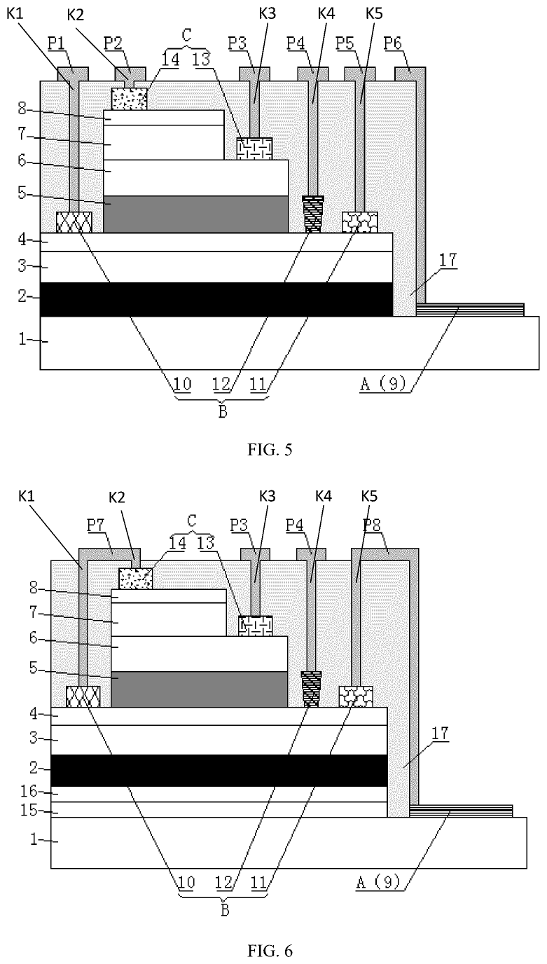

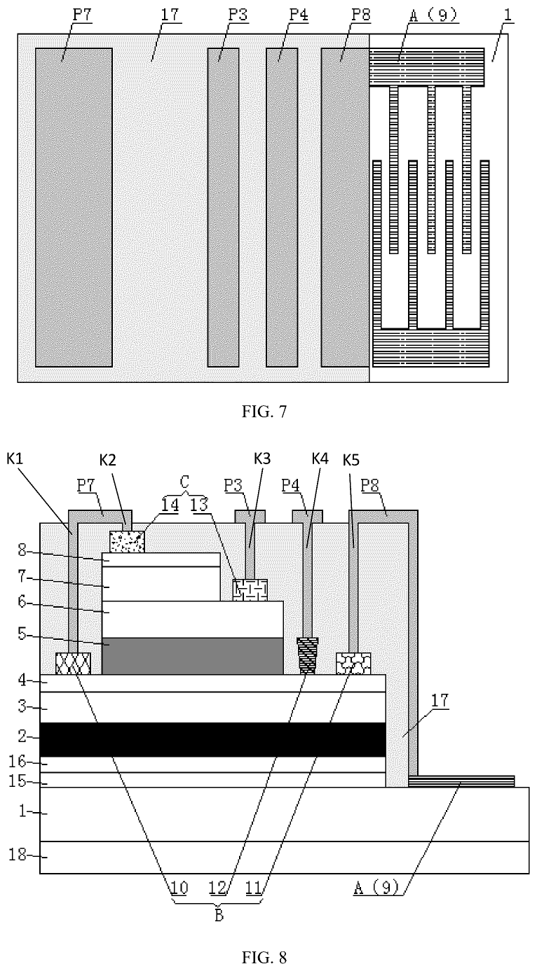

In some embodiments of the present disclosure, as shown in FIG. 6 and FIG. 7, the first pad P1 and the second pad P2 are an integrally formed first integrated pad P7; the fifth pad P5 and the sixth pad P6 are an integrally formed second integrated pad P8.

The PD and the transistor are electrically connected through the integrally formed first integrated pad P7, and the transistor and the LED are electrically connected through the integrally formed second integrated pad P8, which can reduce the number of pads, thereby reducing process cost, wiring complexity, and the risk of soldering defects, improving connection reliability, and also saving layout space, making it suitable for device miniaturization requirements.

In some embodiments of the present disclosure, referring to FIG. 6, an epitaxial stack including a nucleation layer 15 and a buffer layer 16 may be used to further improve the overall performance of the semiconductor device.

To improve the light extraction efficiency of the semiconductor device, making it suitable for scenarios with high brightness requirements, in one or more embodiments of the present disclosure, referring to FIG. 4, FIG. 5, or FIG. 6, the passivation layer 17 may include an insulating reflective structure, so that the light emitted by the LED can exit from the substrate 1. In this embodiment, the substrate 1 may be a transparent substrate, and the light emitted by the LED can exit from the substrate 1.

Alternatively, to improve the light extraction efficiency of the semiconductor device, making it suitable for scenarios with high brightness requirements, as shown in FIG. 8, in another embodiment of the present disclosure, a metal reflection layer 18 may be provided on a surface of the substrate 1 away from the epitaxial stack, so that the light emitted by the LED can exit from the side of the LED. In this embodiment, the passivation layer 17 does not have a reflective effect.

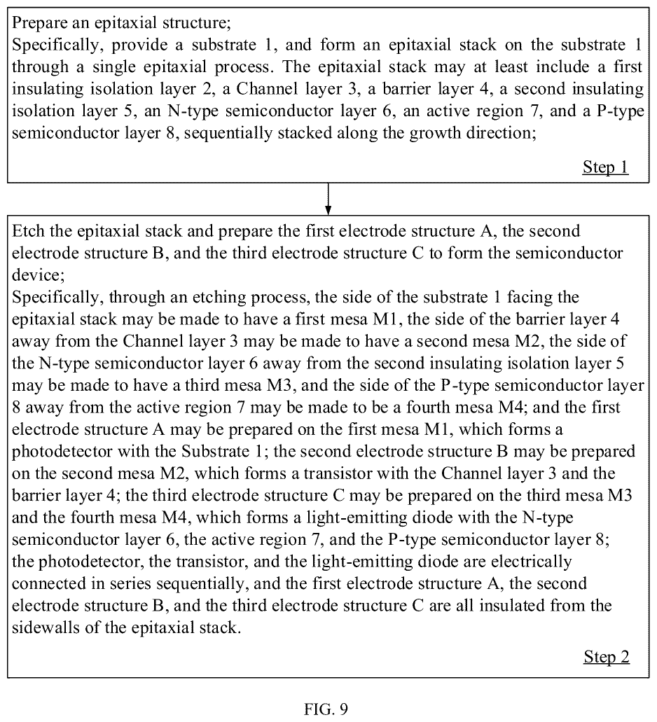

FIG. 9 is a flowchart of a manufacturing method of a semiconductor device according to one or more embodiments of the present disclosure. As shown in FIG. 9, the manufacturing method includes:
Step 1: Prepare an epitaxial structure.

Specifically, referring to FIG. 1, provide a substrate 1, and form an epitaxial stack on the substrate 1 through a single epitaxial process. The epitaxial stack may at least include a first insulating isolation layer 2, a Channel layer 3, a barrier layer 4, a second insulating isolation layer 5, an N-type semiconductor layer 6, an active region 7, and a P-type semiconductor layer 8, sequentially stacked along the growth direction;

By forming the epitaxial stack through a single epitaxial process and integrating multiple wide-bandgap semiconductor materials using a single epitaxial method, the material preparation process may be simplified, laying the foundation for the monolithic integration of different wide-bandgap semiconductor devices.

In one or more embodiments of the present disclosure, Step 1 may include the following steps:
Step A01: Provide a substrate 1;
Step A02: Using an MOCVD (Metal-Organic Chemical Vapor Deposition) equipment, set the growth pressure inside the reaction chamber to 100-200 Torr, the growth temperature to 900-1100 degrees Celsius, continuously introduce ammonia gas and an aluminum source, or ammonia gas and a gallium source, or ammonia gas, a gallium source, and an indium source, or ammonia gas, a gallium source, and an aluminum source into the reaction chamber for a duration of 1-1000 s, to grow the first insulating isolation layer 2 on the substrate 1;
Step A03: Set the growth pressure inside the reaction chamber to 100-200 Torr, the growth temperature to 1000-1100 degrees Celsius, continuously introduce a gallium source and ammonia gas into the reaction chamber for a duration of 1-1500 s, to grow the channel layer on the first insulating isolation layer 2;
Step A04: Set the growth pressure inside the reaction chamber to 100-200 Torr, the growth temperature to 1000-1100 degrees Celsius, continuously introduce ammonia gas and an aluminum source, or ammonia gas, a gallium source, and an aluminum source, or ammonia gas, a gallium source, and an indium source, or ammonia gas, a gallium source, an aluminum source, and an indium source into the reaction chamber for a duration of 1-100 s, to grow the barrier layer 4 on the channel layer;
Step A05: Set the growth pressure inside the reaction chamber to 100-200 Torr, the growth temperature to 900-1100 degrees Celsius, continuously introduce ammonia gas and an aluminum source, or ammonia gas and a gallium source, or ammonia gas, a gallium source, and an indium source, or ammonia gas, a gallium source, and an aluminum source into the reaction chamber for a duration of 1-1000 s, to grow the second insulating isolation layer 5 on the barrier layer 4;
Step A06: Set the growth pressure inside the reaction chamber to 100-500 Torr, the growth temperature to 1000-1100 degrees Celsius, continuously introduce ammonia gas and a gallium source into the reaction chamber, and perform N-type doping to grow the N-type semiconductor layer 6 on the second insulating isolation layer 5. For example, the doping source for N-type doping may be Si;
Step A07: Set the growth pressure inside the reaction chamber to 100-500 Torr, the growth temperature to 700-900 degrees Celsius, continuously introduce a gallium source, ammonia gas, and an indium source into the reaction chamber to form a well layer, stop introducing the indium source into the reaction chamber to form a barrier layer, and repeat the alternate growth of well layers and barrier layers to form the active region 7;
Step A08: Set the growth pressure inside the reaction chamber to 100-500 Torr, the growth temperature to 900-1100 degrees Celsius, continuously introduce a gallium source and ammonia gas into the reaction chamber, and perform P-type doping to grow the P-type semiconductor layer 8 on the active region 7. For example, the doping source for P-type doping may be Mg.

In some embodiments of the present disclosure, high-purity H₂ (hydrogen) or high-purity N₂ (nitrogen) or a mixture of high-purity H₂ and high-purity N₂ may be used as the carrier gas, trimethylgallium (TMGa) and triethylgallium (TEGa) may be used as a gallium source, trimethylindium (TMIn) may be used as an indium source, trimethylaluminum (TMAl) may be used as an aluminum source, and ammonia gas (NH₃) may be used as a nitrogen source.
Step 2: Etch the epitaxial stack and prepare the first electrode structure A, the second electrode structure B, and the third electrode structure C to form the semiconductor device;

Specifically, referring to FIG. 3, through an etching process, the side of the substrate 1 facing the epitaxial stack may be made to have a first mesa M1, the side of the barrier layer 4 away from the Channel layer 3 may be made to have a second mesa M2, the side of the N-type semiconductor layer 6 away from the second insulating isolation layer 5 may be made to have a third mesa M3, and the side of the P-type semiconductor layer 8 away from the active region 7 may be made to be a fourth mesa M4; and the first electrode structure A may be prepared on the first mesa M1, which forms a photodetector with the Substrate 1; the second electrode structure B may be prepared on the second mesa M2, which forms a transistor with the Channel layer 3 and the barrier layer 4; the third electrode structure C may be prepared on the third mesa M3 and the fourth mesa M4, which forms a LED with the N-type semiconductor layer 6, the active region 7, and the P-type semiconductor layer 8.

The photodetector, the transistor, and the LED are electrically connected in series sequentially, and the first electrode structure A, the second electrode structure B, and the third electrode structure C are all insulated from the sidewalls of the epitaxial stack.

The photodetector, the transistor, and the LED are integrated in the same module in a vertically stacked manner through epitaxy. The photodetector, the transistor, and the LED are electrically connected in series sequentially. After the semiconductor device is connected to a working power supply, the photodetector receives the ultraviolet light signal. The Ga2O3 material used by the photodetector can absorb ultraviolet light and generate a photocurrent. Under the action of the electric field, the photocurrent flows from the photodetector into the transistor, the transistor amplifies the photocurrent and drives the LED to emit visible light, realizing the function of intuitive and real-time monitoring of ultraviolet light.

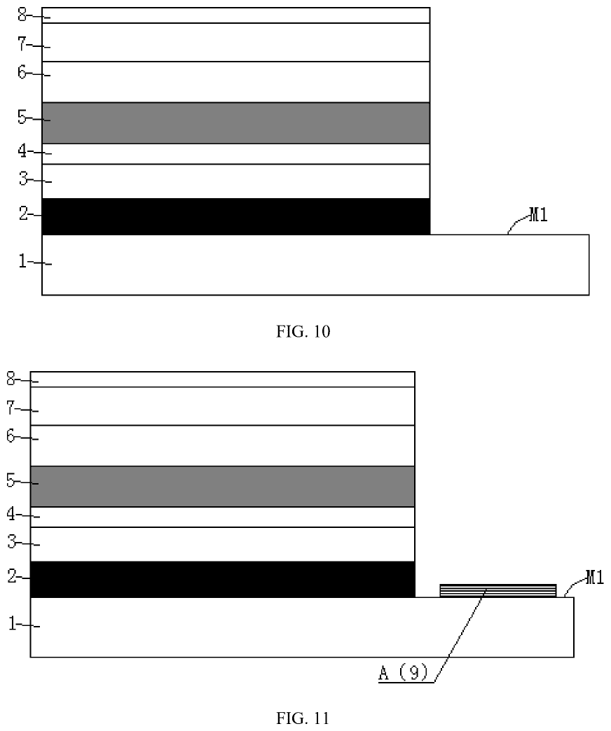

In one or more embodiments of the present disclosure, Step 2 may include the following steps:
Step B01: As shown in FIG. 10, perform a first photolithography to etch the epitaxial stack to form the first mesa M1;

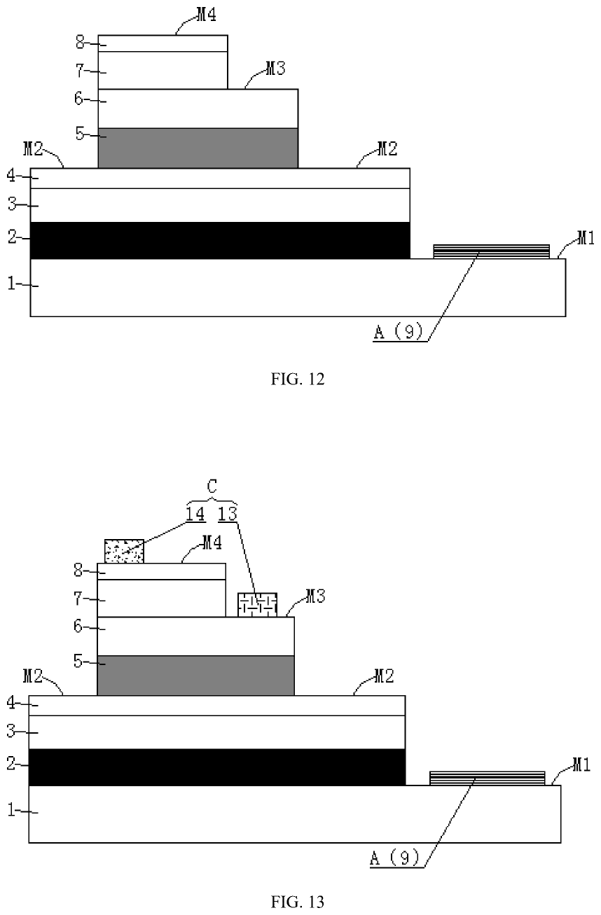

Specifically, define a first mesa preset area on the surface of the epitaxial stack, etch along the first mesa preset area to expose the substrate 1, forming the first mesa M1;
Step B02: As shown in FIG. 11, prepare the first electrode structure A on the first mesa M1;
Step B03: As shown in FIG. 12, perform a second photolithography to etch the epitaxial stack, simultaneously forming the second mesa M2, the third mesa M3, and the fourth mesa M4;

Specifically, determine a second mesa preset area and a third mesa preset area on the upper surface of the epitaxial stack, etch along the second mesa preset area to expose the barrier layer 4, forming the second mesa M2; simultaneously etch along the third mesa preset area to expose the N-type semiconductor layer 6, forming the third mesa M3; and, the surface of the P-type semiconductor layer 8 away from the active region 7 is the fourth mesa M4;
Step B04: As shown in FIG. 13, prepare the third electrode structure C on the third mesa M3 and the fourth mesa M4;
Step B05: Referring to FIG. 3, prepare the second electrode structure B on the second mesa M2.

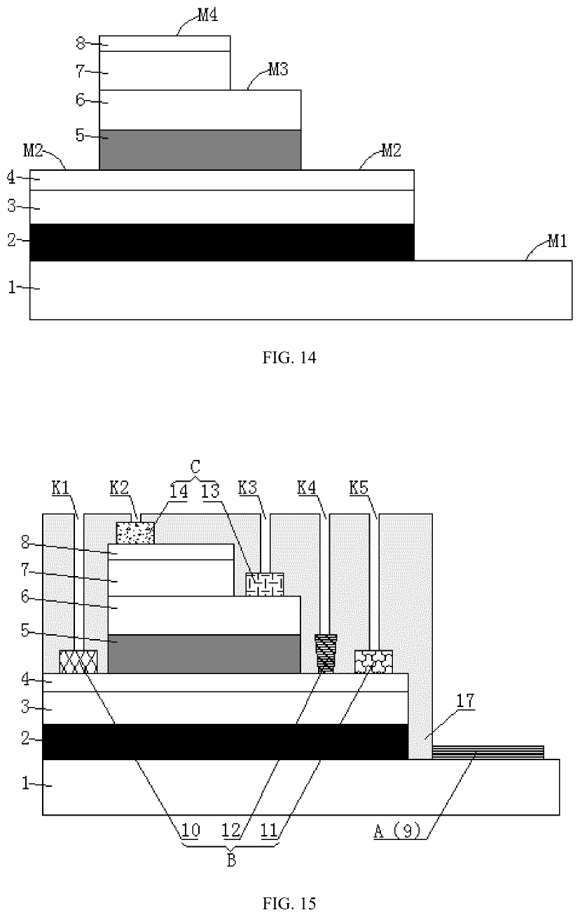

In another embodiment of the present disclosure, Step 2 may include the following steps:
Step C01: As shown in FIG. 14, through one photolithography step, etch part of the surface of the epitaxial stack to simultaneously form the first mesa M1, the second mesa M2, the third mesa M3, and the fourth mesa M4;

Specifically, define a first mesa preset area, a second mesa preset area, and a third mesa preset area on the upper surface of the epitaxial stack, etch along the first mesa preset area to expose the substrate 1, forming the first mesa M1; etch along the second mesa preset area to expose the barrier layer 4, forming the second mesa M2; simultaneously etch along the third mesa preset area to expose the N-type semiconductor layer 6, forming the third mesa M3; and, the surface of the P-type semiconductor layer 8 away from the active region 7 is the fourth mesa M4;
Step C02: Referring to FIG. 12, prepare the first electrode structure A on the first mesa M1;
Step C03: Referring to FIG. 13, prepare the third electrode structure C on the third mesa M3 and the fourth mesa M4;
Step C04: Referring to FIG. 3, prepare the second electrode structure B on the second mesa M2.

By using one photolithography step, the first mesa M1, the second mesa M2, the third mesa M3, and the fourth mesa M4 can be formed simultaneously, saving process steps.

In some embodiments of the present disclosure, the Substrate 1 may be a Ga2O3 substrate (for example, a β—Ga₂O₃ substrate).

In some embodiments of the present disclosure, the lattice constant of the first insulating isolation layer 2 may be between the lattice constant of the Substrate 1 and the lattice constant of the Channel layer 3.

In some embodiments of the present disclosure, the lattice constant of the second insulating isolation layer 5 may be between the lattice constant of the barrier layer 4 and the lattice constant of the N-type semiconductor layer 6.

In some embodiments of the present disclosure, the first insulating isolation layer 2 or the second insulating isolation layer 5 may include nitride high-resistance materials.

In some embodiments of the present disclosure, the first insulating isolation layer 2 or the second insulating isolation layer 5 may include, but are not limited to, a single nitride layer, or different combination structures of multiple nitride layers.

In some embodiments of the present disclosure, the first insulating isolation layer 2 or the second insulating isolation layer 5 may include, but are not limited to, a single AlN layer, a single C-doped GaN layer, a single Fe-doped GaN layer, an AlN/GaN superlattice structure, an AlN/AlGaN superlattice structure, or multiple AlGaN layers with different Al compositions.

In some embodiments of the present disclosure, the thickness range of the first insulating isolation layer 2 or the second insulating isolation layer 5 may be 0.02 μm to 3 μm, including endpoint values. For example, the thickness of the first insulating isolation layer 2 may be 0.02 μm, 1 μm, 2 μm, or 3 μm, and the thickness of the second insulating isolation layer 5 may be 0.02 μm, 1 μm, 2 μm, or 3 μm.

The specific materials and thicknesses of the first insulating isolation layer 2 and the second insulating isolation layer 5 are not limited to the embodiments of the present disclosure. The materials and thicknesses of the first insulating isolation layer 2 and the second insulating isolation layer 5 may be the same or different. In one or more embodiments of the present disclosure, the first insulating isolation layer 2 may be a C-doped GaN high-resistance layer with a thickness of 2 μm, and the second insulating isolation layer 5 may be an Fe-doped GaN high-resistance layer with a thickness of 1 μm.

In some embodiments of the present disclosure, the thickness range of the channel layer 3 may be 10 nm to 1500 nm, including endpoint values. For example, the thickness of the channel layer 3 may be 10 nm, 100 nm, 200 nm, 300 nm, or 1500 nm.

In some embodiments of the present disclosure, the barrier layer 4 may include, but is not limited to, one or more of an AlN layer, an AlGaN layer, an InAlGaN layer, an InAlN layer, and an AlN/GaN superlattice structure.

In some embodiments of the present disclosure, the thickness range of the barrier layer 4 may be 2 nm to 40 nm, including endpoint values. For example, the thickness of the barrier layer 4 may be 2 nm, 20 nm, or 40 nm.

In some embodiments of the present disclosure, the thickness range of the N-type semiconductor layer 6 may be 0.5 μm to 4 μm, including endpoint values. For example, the thickness of the N-type semiconductor layer 6 may be 0.5 μm, 2 μm, or 4 μm.

In some embodiments of the present disclosure, the thickness range of the P-type semiconductor layer 8 may be 20 nm to 300 nm, including endpoint values. For example, the thickness of the P-type semiconductor layer 8 may be 20 nm, 50 nm, 100 nm, 200 nm, or 300 nm.

In some embodiments of the present disclosure, the active region 7 may be a periodic structure composed of well layers and barrier layers. The thickness range of the active region 7 may be 10 nm to 200 nm, including endpoint values. For example, the thickness of the active region 7 may be 10 nm, 50 nm, 100 nm, or 200 nm.

The specific materials of the N-type semiconductor layer 6 and the P-type semiconductor layer 8 are not limited to the embodiments of the present disclosure.

In one or more embodiments of the present disclosure, the N-type semiconductor layer 6 may be an N-type GaN layer, the P-type semiconductor layer 8 may be a P-type GaN layer, and the active region 7 may be an InGaN/GaN multiple quantum well layer.

In some embodiments of the present disclosure, referring to FIG. 2, the epitaxial stack further may include a nucleation layer 15 and a buffer layer 16 located between the substrate 1 and the first insulating isolation layer 2 and sequentially stacked in the direction toward the first insulating isolation layer 2, used for lattice transition and effectively reducing stress, which can further improve the crystal quality of the epitaxial stack.

In some embodiments of the present disclosure, the nucleation layer 15 may include, but is not limited to, one or more of an AlN layer, a GaN layer, and an AlGaN layer.

In some embodiments of the present disclosure, the thickness range of the nucleation layer 15 may be 5 nm to 500 nm, including endpoint values. For example, the thickness of the nucleation layer 15 may be 5 nm, 200 nm, or 500 nm.

In some embodiments of the present disclosure, the first electrode structure A may be a PD electrode 9. The second electrode structure B may include: a drain pad 10, a source pad 11, and a gate pad 12, wherein the drain pad 10 and the source pad 11 both form Ohmic contacts with the barrier layer 4, and the gate pad 12 forms a Schottky contact with the barrier layer 4. The third electrode structure C may include: an N electrode 13 located on the third mesa M3 and a P electrode 14 located on the fourth mesa M4.

After the semiconductor device is connected to a working power supply, the photocurrent flows from electrode 9 of the PD into the source pad 11 of the transistor, then flows out from the drain pad 10 of the transistor, then flows into the P electrode 14 of the LED, and then flows out from the N electrode 13 of the LED.

In some embodiments of the present disclosure, the drain pad 10, the source pad 11, and the gate pad 12 may be spaced apart from each other, or the N electrode 13 and the P electrode 14 may be arranged away from each other.

In some embodiments of the present disclosure, the PD electrode 9 may include, but is not limited to, an interdigitated electrode. The interdigitated electrode may include alternately arranged finger-shaped electrodes, forming dense electrode pairs, which can improve carrier collection efficiency. A parallel electric field can be formed between adjacent finger-shaped electrodes, making the electric field distribution more uniform, thereby improving the performance of the PD.

In some embodiments of the present disclosure, the drain pad 10 and the source pad 11 are located on both sides of the gate pad 12, and the gate pad 12 may be used to control the current to achieve field-effect modulation.

In some embodiments of the present disclosure, the drain pad 10 may be disposed close to the P electrode side to facilitate subsequent connection between the drain pad 10 and the P electrode.

In some embodiments of the present disclosure, the second insulating isolation layer 5 and the LED may be located between the source pad 11 and the gate pad 12.

The second insulating isolation layer 5 can improve the dielectric withstand capability between the source pad 11 and the gate pad 12, thereby enhancing the withstand voltage capability of the HEMT.

In some embodiments of the present disclosure, referring to FIG. 3, the second insulating isolation layer 5 and the LED may be located between the drain pad 10 and the gate pad 12. The second insulating isolation layer 5 can improve the dielectric withstand capability between the drain pad 10 and the gate pad 12, thereby enhancing the withstand voltage capability of the HEMT, and the gate pad 12 may be disposed close to the source pad 11 to reduce field-effect modulation delay.

In some embodiments of the present disclosure, the drain pad 10, the source pad 11, and the gate pad 12 may be prepared by the following steps:

Prepare the drain pad 10 and the source pad 11 on the second mesa M2 by metal deposition, then perform a laser annealing process so that both the drain pad 10 and the source pad 11 form Ohmic contacts with the barrier layer 4. In one or more embodiments of the present disclosure, the laser annealing time may be 1 minute;

Prepare the gate pad 12 on the second mesa M2 by metal deposition.

In some embodiments of the present disclosure, the PD electrode 9 may include, but is not limited to, one or more stacks of a Ti layer and an Au layer. The thickness of the Ti layer may be 20 nm, and the thickness of the Au layer may be 120 nm.

In some embodiments of the present disclosure, the gate pad 12 may include, but is not limited to, one or more stacks of an Ni layer and an Au layer. The thickness of the Ni layer may be 60 nm, and the thickness of the Au layer may be 100 nm.

In some embodiments of the present disclosure, the source pad 11 may include, but is not limited to, one or more stacks of a Ti layer, an Al layer, an Ni layer, and an Au layer, wherein the thickness of the Ti layer may be 20 nm, the thickness of the Al layer may be 120 nm, the thickness of the Ni layer may be 40 nm, and the thickness of the Au layer may be 50 nm.

In some embodiments of the present disclosure, the drain pad 10 may include, but is not limited to, one or more stacks of a Ti layer, an Al layer, an Ni layer, and an Au layer, wherein the thickness of the Ti layer may be 20 nm, the thickness of the Al layer may be 120 nm, the thickness of the Ni layer may be 40 nm, and the thickness of the Au layer may be 50 nm.

In some embodiments of the present disclosure, the connection between the photodetector and the transistor, and the connection between the transistor and the LED may be achieved by external wire bonding.

Specifically, referring to FIG. 3, the PD electrode 9 of the photodetector may be electrically connected to the source pad 11 of the transistor through a first external metal connection line 20, and the drain pad 10 of the transistor may be electrically connected to the P electrode 14 of the LED through a second external metal connection line 21.

In some embodiments of the present disclosure, referring to FIG. 4, the semiconductor device further may include a passivation layer 17 covering the exposed surfaces of the epitaxial stack.

The first electrode structure A, the second electrode structure B, and the third electrode structure C are insulated from the sidewalls of the epitaxial stack through the passivation layer 17. The material of the passivation layer 17 may be silicon oxide, silicon nitride, or other materials with passivation effects, which are not limited to the embodiments of the present disclosure.

In some embodiments of the present disclosure, a chemical vapor deposition process may be used to form the passivation layer 17.

In some embodiments of the present disclosure, the connection between the photodetector and the transistor, and the connection between the transistor and the LED can also be achieved by directly setting metal connection lines on the passivation layer, without the need for additional external wire bonding.

Specifically, referring to FIG. 4, the PD electrode 9 of the photodetector may be electrically connected to the source pad 11 of the transistor through a first internal metal connection line 30, and the drain pad 10 of the transistor may be electrically connected to the P electrode 14 of the LED through a second internal metal connection line 31.

In some embodiments of the present disclosure, referring to FIG. 5, the passivation layer 17 covers the exposed surfaces of the second electrode structure B and the third electrode structure C, and exposes the first electrode structure A. The passivation layer 17 may include through hole structures K1-K5 penetrating through the passivation layer 17. The first electrode structure A, the second electrode structure B, and the third electrode structure C are electrically connected to the epitaxial stack on the substrate 1 through these through hole structures.

As shown in FIG. 15, the through hole structures K1-K5 of the passivation layer 17 may include a first through hole K1, a second through hole K2, a third through hole K3, a fourth through hole K4, and a fifth through hole K5 penetrating through the passivation layer 17. The semiconductor device may further include: a first pad P1, a second pad P2, a third pad P3, a fourth pad P4, a fifth pad P5, and a sixth pad P6 located on a side of the passivation layer 17 away from the Substrate 1. The first pad P1 may be connected to the drain pad 10 by embedding in the first through hole K1; the second pad P2 may be connected to the P electrode 14 by embedding in the second through hole K2; the third pad P3 may be connected to the N electrode 13 by embedding in the third through hole K3; the fourth pad P4 may be connected to the gate pad 12 by embedding in the fourth through hole K4; the fifth pad P5 may be connected to the source pad 11 by embedding in the fifth through hole K5; the sixth pad P6 may be connected to the PD electrode 9 by extending to the sidewall of the passivation layer 17.

In some embodiments of the present disclosure, a deep hole etching process may be used to form the first through hole K1, the second through hole K2, the third through hole K3, the fourth through hole K4, or the fifth through hole K5.

The first electrode structure A may be exposed to avoid the passivation layer 17 affecting the photoelectric reception of the photodetector.

The second pad P2, the third pad P3, the fourth pad P4, the fifth pad P5, or the sixth pad P6 may include, but are not limited to, one or more metal stacks of Al, Cu, Au, TiN, Ti, Pt, Cr, Ni, Pd, which are not limited in this embodiment of the present application.

In one or more embodiments of the present disclosure, the material of the first pad P1, the second pad P2, the third pad P3, the fourth pad P4, the fifth pad P5, or the sixth pad P6 may be Al.

The specific thickness of the passivation layer 17 is not limited to the embodiments of the present disclosure. In one or more embodiments of the present disclosure, the thickness of the passivation layer 17 may be 2 μm.

In some embodiments of the present disclosure, the surfaces of the first pad P1, the second pad P2, the third pad P3, the fourth pad P4, the fifth pad P5, and the sixth pad P6 away from the passivation layer 17 may be at the same level height, which can reduce soldering defects and avoid device tilting or suspension, thereby improving device stability.

In some embodiments of the present disclosure, referring to FIG. 6 and FIG. 7, the first pad P1 and the second pad P2 are an integrally formed first integrated pad P7; the fifth pad P5 and the sixth pad P6 are an integrally formed second integrated pad P8.

The photodetector and the transistor are electrically connected through the integrally formed first integrated pad P7, and the transistor and the LED are electrically connected through the integrally formed second integrated pad P8, which can reduce the number of pads, thereby reducing process cost, wiring complexity, and the risk of soldering defects, improving connection reliability, and also saving layout space, making it suitable for device miniaturization requirements.

In some embodiments of the present disclosure, referring to FIG. 6, an epitaxial structure including a nucleation layer 15 and a buffer layer 16 may be used to further improve the overall performance of the semiconductor device.

To improve the light extraction efficiency of the semiconductor device, making it suitable for scenarios with high brightness requirements, in one or more embodiments of the present disclosure, referring to FIG. 4, FIG. 5, or FIG. 6, the passivation layer 17 may include an insulating reflective structure, so that the light emitted by the LED can exit from the Substrate 1. In this embodiment, the substrate 1 may be a transparent substrate, and the light emitted by the LED can exit from the substrate 1.

Alternatively, to improve the light extraction efficiency of the semiconductor device, making it suitable for scenarios with high brightness requirements, referring to FIG. 8, in another optional embodiment of this application, a metal reflection layer 18 may be provided on a surface of the substrate 1 away from the epitaxial stack, so that the light emitted by the LED can exit from the side of the LED. In this embodiment, the passivation layer 17 does not have a reflective effect.

Through the above technical solutions, at least the following effects are achieved:

The epitaxial structure provided in this embodiment may include: a substrate; an epitaxial stack disposed on the substrate, the epitaxial stack at least including: a first insulating isolation layer, a channel layer, a barrier layer, a second insulating isolation layer, an N-type semiconductor layer, an active region, and a P-type semiconductor layer sequentially stacked from bottom to top on the substrate. This epitaxial structure monolithically integrates multiple wide-bandgap semiconductor materials, wherein the substrate may be used to form a photodetector, the channel layer and the barrier layer may be used to form a transistor, and the N-type semiconductor layer, the active region, and the P-type semiconductor layer may be used to form a LED, for manufacturing a semiconductor device that enables intuitive, real-time monitoring of ultraviolet light. It does not require an additional electrical signal processing system to feedback detection information and can meet the miniaturization requirements of solar-blind ultraviolet detectors.

Furthermore, the substrate may be a Ga₂O₃ substrate, and the epitaxial stack may be obtained by a single epitaxial growth on the Ga₂O₃ substrate. Ga₂O₃ semiconductor material has wide-bandgap characteristics (bandgap~4.8 eV), excellent thermal stability, and chemical inertness, making it suitable for high-temperature epitaxial growth environments. Forming the first insulating isolation layer on the Ga₂O₃ substrate utilizes its high insulation and thermal matching with the Ga₂O₃ substrate to isolate the Ga₂O₃ substrate from subsequent functional layers, reducing leakage current. Moreover, the lattice constant of the first insulating isolation layer may be between the lattice constant of the substrate and the lattice constant of the channel layer, allowing the first insulating isolation layer to effectively alleviate the lattice mismatch between the substrate and the channel layer, reduce dislocation density, and provide a high-quality template for subsequent multi-layer growth. Utilizing the lattice compatibility and thermal matching characteristics of the substrate and the epitaxial functional layers, the epitaxial stack may be directly obtained by a single epitaxial growth. Moreover, integrating multiple wide-bandgap semiconductor materials using a single epitaxial method can simplify the material preparation process, laying the foundation for the monolithic integration of different wide-bandgap semiconductor devices.

Furthermore, setting the lattice constant of the second insulating isolation layer between the lattice constant of the barrier layer and the lattice constant of the N-type semiconductor layer allows the second insulating isolation layer to effectively alleviate the lattice mismatch between the barrier layer and the N-type semiconductor layer, thereby improving the crystal quality of the epitaxial stack.

Furthermore, the first insulating isolation layer or the second insulating isolation layer may include high-resistance nitride materials, offering high flexibility in lattice matching, making it easier to control the lattice constant of the high-resistance nitride materials to act as a lattice transition, and reducing mismatch. Moreover, the thermal expansion coefficient of high-resistance nitride materials is close to that of III-V (wide-bandgap) materials, which can reduce cracks caused by thermal stress. Additionally, high-resistance nitride materials have high chemical stability, and nitrides can inhibit diffusion reactions between the functional layers on both sides of the high-resistance nitride material at high temperatures.

The semiconductor device provided by the embodiments of the present disclosure uses the epitaxial structure described in any of the above embodiments, wherein the first electrode structure forms a photodetector with the substrate, the second electrode structure forms a transistor with the channel layer and the barrier layer, and the third electrode structure forms a LED with the N-type semiconductor layer, the active region, and the P-type semiconductor layer. The photodetector, the transistor, and the LED are electrically connected in series sequentially. This semiconductor device integrates the photodetector, the transistor, and the LED in the same module in a vertically stacked manner, which can meet the miniaturization requirements of solar-blind ultraviolet detectors. Moreover, the wide bandgap of the substrate corresponds to the absorption of the solar-blind ultraviolet band (240-280 nm), enabling the photodetector to receive ultraviolet light signals. The channel layer and the barrier layer serve as the core structure of the transistor. At the heterojunction interface between the channel layer and the barrier layer, due to polarization effects and band offset, electrons are confined within a nanoscale thin layer, forming a high-concentration, high-mobility two-dimensional electron gas (2DEG) to achieve photocurrent amplification. The N-type semiconductor layer and the P-type semiconductor layer achieve carrier control through N-type doping and P-type doping, respectively, and recombination luminescence occurs in the active region, enabling the LED to emit visible light.

After the semiconductor device is connected to a working power supply, the photodetector receives the ultraviolet light signal, leveraging the advantages of Ga₂O₃ material used by the photodetector in ultraviolet detection to receive ultraviolet light and generate a photocurrent. Under the action of the electric field, the photocurrent flows from the photodetector into the transistor. The transistor amplifies the photocurrent and drives the LED to emit visible light, realizing the function of intuitive and real-time monitoring of ultraviolet light. This has broad application prospects in scenarios such as corona monitoring, fire detection, and full-duplex indoor optical communication.

In addition, the channel layer and the barrier layer are disposed between the first insulating isolation layer and the second insulating isolation layer. This structural design can effectively suppress the hot electron emission effect of the transistor, significantly reduce the generation of leakage current, and will not adversely affect the photodetector and the LED. At the same time, this design enhances the withstand voltage performance of the device under high voltage, reducing the risk of breakdown.

Furthermore, the provision of the first insulating isolation layer can improve the crystal quality of the transistor, and the provision of the second insulating isolation layer can improve the crystal quality of the LED, thereby enhancing the overall performance of the semiconductor device.

The manufacturing method of the semiconductor device provided in this embodiment, while achieving the beneficial effects of the aforementioned semiconductor device, integrates multiple wide-bandgap semiconductor materials using an epitaxial method, simplifying the material preparation process and enabling the monolithic integration and preparation of different wide-bandgap semiconductor devices on the same substrate. The manufacturing method is suitable for traditional integrated circuit device fabrication processes, is simple and convenient to produce, facilitates mass production, and does not increase additional device preparation costs.

In the present disclosure, the orientation or positional relationships indicated by the terms “lateral”, “longitudinal”, “upper”, “lower”, etc., are based on the orientation or positional relationships shown in the accompanying drawings, and are only for the convenience of describing the present disclosure and simplifying the description, rather than indicating or implying that the referred device or element must have a specific orientation, be constructed and operate in a specific orientation. Therefore, the above terms should not be understood as limitations to the present disclosure.

The above description of the disclosed embodiments enables those skilled in the art to make or use the present disclosure. The generic principles defined herein may be practiced in other embodiments without departing from the spirit or scope of the application. Therefore, the present disclosure is not to be limited to the embodiments shown herein but is to be accorded the widest scope consistent with the principles and novel features disclosed herein.

What is claimed is:

1. An epitaxial structure, comprising:
a substrate; and
an epitaxial stack disposed on the substrate, the epitaxial stack comprising: a first insulating isolation layer, a channel layer, a barrier layer, a second insulating isolation layer, an N-type semiconductor layer, an active region, and a P-type semiconductor layer, sequentially stacked from bottom to top on the substrate.

2. The epitaxial structure according to claim 1, wherein the substrate is a Ga₂O₃ substrate; or
the channel layer is a GaN channel layer.

3. The epitaxial structure according to claim 1, wherein a lattice constant of the first insulating isolation layer is between a lattice constant of the substrate and a lattice constant of the channel layer; or
a lattice constant of the second insulating isolation layer is between a lattice constant of the barrier layer and a lattice constant of the N-type semiconductor layer.

4. The epitaxial structure according to claim 1, wherein the first insulating isolation layer or the second insulating isolation layer comprises a high-resistance nitride material.

5. The epitaxial structure according to claim 1, wherein the epitaxial stack further comprises:
a nucleation layer and a buffer layer, located between the substrate and the first insulating isolation layer and sequentially stacked in a direction toward the first insulating isolation layer.

6. A semiconductor device, comprising:
an epitaxial structure comprising: a substrate and an epitaxial stack disposed on the substrate,
wherein the epitaxial stack comprises: a first insulating isolation layer, a channel layer, a barrier layer, a second insulating isolation layer, an N-type semiconductor layer, an active region, and a P-type semiconductor layer, sequentially stacked from bottom to top on the substrate.

7. The semiconductor device according to claim 6, further comprising:
a first electrode structure, configured with the substrate as a photodetector;
a second electrode structure, configured with the channel layer and the barrier layer as a transistor; or
a third electrode structure, configured with the N-type semiconductor layer, the active region, and the P-type semiconductor layer as a light-emitting diode (LED).

8. The semiconductor device according to claim 7, comprising the first electrode structure, the second electrode structure, and the third electrode structure;
wherein the photodetector, the transistor, and the LED are electrically connected in series sequentially, and the first electrode structure, the second electrode structure, or the third electrode structure is insulated from a sidewall of the epitaxial stack.

9. The semiconductor device according to claim 7, wherein a side of the substrate facing the epitaxial stack has a first mesa, and the first electrode structure is located on the first mesa;
a side of the barrier layer away from the channel layer has a second mesa, and the second electrode structure is located on the second mesa; or
a side of the N-type semiconductor layer away from the second insulating isolation layer has a third mesa, and a side of the P-type semiconductor layer away from the active region has a fourth mesa, and the third electrode structure is located on the third mesa and the fourth mesa.

10. The semiconductor device according to claim 9, wherein the first electrode structure is a photodetector (PD) electrode;
the second electrode structure comprises: a drain pad, a source pad, and a gate pad, wherein the drain pad and the source pad both form Ohmic contacts with the barrier layer, and the gate pad forms a Schottky contact with the barrier layer; or
the third electrode structure comprises: an N electrode located on the third mesa and a P electrode located on the fourth mesa.

11. The semiconductor device according to claim 7, wherein the semiconductor device further comprises a passivation layer covering exposed surfaces of the epitaxial stack.

12. The semiconductor device according to claim 11, comprising the first electrode structure, the second electrode structure, and the third electrode structure;
wherein the passivation layer covers exposed surfaces of the second electrode structure and the third electrode structure, and exposes the first electrode structure, the passivation layer comprises through hole structures penetrating through the passivation layer, and the first electrode structure, the second electrode structure, and the third electrode structure are electrically connected to the epitaxial stack on the substrate through the through hole structures.

13. The semiconductor device according to claim 12, wherein
the first electrode structure is a PD electrode;
wherein the second electrode structure comprises: a drain pad, a source pad, and a gate pad, wherein the drain pad and the source pad both form Ohmic contacts with the barrier layer, and the gate pad forms a Schottky contact with the barrier layer;
wherein the third electrode structure comprises: an N electrode located on the third mesa and a P electrode located on the fourth mesa;
wherein the through hole structures of the passivation layer comprise a first via, a second via, a third via, a fourth via, and a fifth through hole penetrating through the passivation layer;
wherein the semiconductor device further comprises: a first pad, a second pad, a third pad, a fourth pad, a fifth pad, and a sixth pad located on a side of the passivation layer away from the substrate; and
wherein the first pad is connected to the drain pad by embedding in the first via; the second pad is connected to the P electrode by embedding in the second via; the third pad is connected to the N electrode by embedding in the third via; the fourth pad is connected to the gate pad by embedding in the fourth via; and the fifth pad is connected to the source pad by embedding in the fifth via; the sixth pad is connected to the PD electrode by extending to a sidewall of the passivation layer.

14. The semiconductor device according to claim 6, wherein the substrate is a Ga₂O₃ substrate; or
the channel layer is a GaN channel layer.

15. The semiconductor device according to claim 6, wherein a lattice constant of the first insulating isolation layer is between a lattice constant of the substrate and a lattice constant of the channel layer; or
a lattice constant of the second insulating isolation layer is between a lattice constant of the barrier layer and a lattice constant of the N-type semiconductor layer.

16. The semiconductor device according to claim 6, wherein the first insulating isolation layer or the second insulating isolation layer comprises a high-resistance nitride material.

17. The semiconductor device according to claim 6, wherein the epitaxial stack further comprises:
a nucleation layer and a buffer layer, located between the substrate and the first insulating isolation layer and sequentially stacked in the direction toward the first insulating isolation layer.

18. A manufacturing method of a semiconductor device, comprising:
forming an epitaxial stack on a substrate through a single epitaxial process,
wherein the epitaxial stack comprises a first insulating isolation layer, a channel layer, a barrier layer, a second insulating isolation layer, an N-type semiconductor layer, an active region, and a P-type semiconductor layer sequentially stacked along a growth direction.

19. The manufacturing method according to claim 18, further comprising:
etching the epitaxial stack to prepare a first electrode structure, a second electrode structure, and a third electrode structure,
wherein the first electrode structure forms a photodetector with the substrate;
the second electrode structure forms a transistor with the channel layer and the barrier layer; and
the third electrode structure forms a LED with the N-type semiconductor layer, the active region, and the P-type semiconductor layer.

20. The manufacturing method according to claim 19, wherein etching the epitaxial stack to prepare the first electrode structure, the second electrode structure, and the third electrode structure comprises:
preparing an etching process on the epitaxial stack, forming a first mesa on a side of the substrate facing the epitaxial stack, a second mesa on a side of the barrier layer away from the channel layer, a third mesa on a side of the N-type semiconductor layer away from the second insulating isolation layer, and a fourth mesa on a side of the P-type semiconductor layer away from the active region; and
preparing the first electrode structure on the first mesa, preparing the second electrode structure on the second mesa, and preparing the third electrode structure on the third mesa and the fourth mesa,
wherein the photodetector, the transistor, and the LED are electrically connected in series sequentially, and the first electrode structure, the second electrode structure, or the third electrode structure is insulated from a sidewall of the epitaxial stack.
